(19) United States
(12) Patent Application Publication
(10) Pub. No.: US 2024/0271277 A1
(43) Pub. Date: Aug. 15, 2024

(54) ATOMIC LAYER DEPOSITION OF GROUP FIFTEEN MATERIALS

(71) Applicant: Applied Materials, Inc., Santa Clara, CA (US)

(72) Inventors: Thomas Joseph Knisley, Livonia, MI (US); Zachary Joseph Devereaux, Webberville, MI (US); Charles Hartger Winter, Bloomfield Hills, MI (US); Daniel Wei Ming Beh, Detroit, MI (US)

(21) Appl. No.: 18/438,175

(22) Filed: Feb. 9, 2024

Related U.S. Application Data
(60) Provisional application No. 63/484,457, filed on Feb. 10, 2023.

(51) Int. Cl. C23C 16/455; C23C 16/02; C23C 16/28

(52) U.S. Cl. CPC C23C 16/45527; C23C 16/0281; C23C 16/28; C23C 16/45553

(57) ABSTRACT

In some aspects of the present disclosure, a method includes performing an atomic layer deposition (ALD) process to form an antimony-containing coating of a surface of a substrate. The ALD process includes providing a first reactant to the surface of the substrate. The first reactant adsorbs onto the surface to form an adsorption layer thereon. The ALD process further includes providing a second reactant to the surface of the substrate. The second reactant includes a reducing agent. The second reactant reacts with the adsorption layer to form a layer of the antimony-containing coating. The ALD process further includes repeating the providing of the first reactant and the providing of the second reactant one or more times to form the antimony-containing coating.

### RELATED APPLICATIONS

This application claims the benefit of U.S. Provisional Patent Application No. 63/484,457, filed Feb. 10, 2023, entitled “ATOMIC LAYER DEPOSITION OF GROUP FIFTEEN MATERIALS,” which is incorporated by reference herein.

### TECHNICAL FIELD

The present disclosure relates to methods associated with atomic layer deposition. More particularly, the present disclosure relates to systems and methods for performing atomic layer deposition of materials including elements of group fifteen of the periodic table.

### BACKGROUND

Products may be produced by performing one or more manufacturing processes using manufacturing equipment. For example, semiconductor manufacturing equipment may be used to produce substrates via semiconductor manufacturing processes. Substrates, such as semiconductor logic devices, may benefit from coatings deposited on one or more surfaces of the substrates. A variety of available coating materials may increase the ability to tune properties of a substrate for a target application.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In some aspects of the present disclosure, a method includes performing an atomic layer deposition (ALD) process to form an antimony-containing coating of a surface of a substrate. The ALD process includes providing a first reactant to the surface of the substrate. The first reactant adsorbs onto the surface to form an adsorption layer thereon. The ALD process further includes providing a second reactant to the surface of the substrate. The second reactant includes a reducing agent. The second reactant reacts with the adsorption layer to form a layer of the antimony-containing coating. The ALD process further includes repeating the providing of the first reactant and the providing of the second reactant one or more times to form the antimony-containing coating.

In some aspects of the present disclosure, a method includes performing an atomic layer deposition (ALD) process to form an bismuth-containing coating of a surface of a substrate. The ALD process includes providing a first reactant to the surface of the substrate. The first reactant adsorbs onto the surface to form an adsorption layer thereon. The ALD process further includes providing a second reactant to the surface of the substrate. The second reactant includes a reducing agent. The second reactant reacts with the adsorption layer to form a layer of the bismuth-containing coating. The ALD process further includes repeating the providing of the first reactant and the providing of the second reactant one or more times to form the bismuth-containing coating.

In some aspects of the present disclosure, a method includes performing an ALD process to form a coating containing a group fifteen element on a surface of a substrate. The ALD process includes providing a first reactant to the surface of the substrate. The first reactant comprises the group fifteen element. The first reactant adsorbs onto the surface of the substrate to form an adsorption layer thereon. The ALD process further includes providing a second reactant to the surface of the substrate. The second reactant includes a reducing agent. The second reactant reacts with the adsorption layer to form a layer of the coating containing the group fifteen element. The ALD process further includes repeating the providing of the first reactant and the providing of the second reactant one or more times to form the coating containing the group fifteen element.

In some aspects of the present disclosure, an article includes a body and a coating deposited on a surface of the body. The body comprises a first material. The coating comprises bismuth.

In some aspects of the present disclosure, an article includes a body and a coating deposited on a surface of the body. The body comprises a first material. The coating comprises a group fifteen element.

### BRIEF DESCRIPTION OF THE DRAWINGS

The present disclosure is illustrated by way of example, and not by way of limitation in the figures of the accompanying drawings.

FIG. 1A illustrates an article upon which a coating is applied, according to some embodiments.

FIG. 1B depicts an article upon which a multi-layered coating is applied, according to some embodiments.

FIG. 2A is a flow diagram of a method for depositing a coating including a group 15 element on a substrate, according to some embodiments.

FIG. 2B is a flow diagram of a method for generating an antimony-containing coating on a substrate, according to some embodiments.

FIG. 2C is a flow diagram of a method for generating a bismuth-containing coating on a substrate, according to some embodiments.

FIG. 2D is a flow diagram of a method for generating a coating including a group 15 element, according to some embodiments.

### DETAILED DESCRIPTION

Described herein are technologies related to generating a coating including bismuth and/or antimony on one or more surfaces of a body, such as a semiconductor device. Properties of a substrate are dependent upon construction of the substrate, including materials used to manufacture the substrate. Adjusting materials used in construction of a substrate, semiconductor device, or the like may generate a device with properties well suited to one or more applications. For example, a semiconductor device may include metal contacts. Properties of the metal material disposed at the contacts of the device have an effect upon operation of the semiconductor device.

A coating may be applied to a substrate such as a semiconductor device to achieve one or more target properties of the substrate. A coating may protect a surface of a substrate from a damaging environment, may adjust the physical, chemical, electrical, or optical properties of the substrate, or the like. Coatings and/or processes for depositing coatings enables greater variation of properties of substrates and devices, greater specificity of a device or substrate for a target application, etc.

Materials of a device affect operation of the device. Composition of metal contacts of logic gates adjusts operation of the gates. Utilizing different materials as coating material of contacts may adjust power consumption of a logic device. Contact coating material may adjust a threshold voltage of a transistor device. In some cases, a work function of a material coating may influence energy consumption of a semiconductor device.

Thin coatings may be applied using a variety of methods. Examples include physical vapor deposition, chemical vapor deposition, atomic layer deposition, electroplating, etc. Various methods have associated disadvantages. Physical vapor deposition techniques (e.g., sputtering, pulsed laser deposition, etc.) are often limited to or most effective in line-of-sight procedures, and may be ineffective at coating an interior volume or a complex surface geometry. Chemical vapor deposition may generate uneven coating depths on components with various portions that have varied availability to the reactive gases. Atomic Layer Deposition (ALD) techniques conventionally involve flooding a chamber containing the target component, allowing diffusion to drive thorough deposition of material.

Methods and systems of the present disclosure enable materials and types of thin coatings to be applied to substrates by ALD. Coatings including metals, non-metals, and metalloids of group fifteen of the periodic table may be generated by methods of the present disclosure. Coatings may include elemental bismuth. Coatings may include elemental antimony. Coatings may include elemental phosphorous and/or arsenic. Coatings may include compounds including group fifteen elements, alloys including group seven elements, etc.

In some embodiments, bismuth and/or antimony may be deposited by ALD. A film or coating of bismuth may be generated on a substrate by ALD. A film or coating of antimony may be generated on a substrate by ALD. A coating of antimony may be generated by repeatedly exposing a surface to be coated to various materials for depositing antimony. Deposition of an antimony coating may include exposing a target surface to an antimony-containing precursor. The antimony precursor may be antimony chloride (SbCl₃). Other antimony precursors may be used, instead of antimony chloride or in addition to antimony chloride. Other antimony precursors may include other antimony halides. Other antimony precursors may include compounds of the form SbX₃, where X represents a halide. Other antimony precursors may include SbF₃, SbBr₃, or SbI₃. Other volatile antimony-containing compounds may be used as antimony precursors for ALD. Antimony precursors may include Sb(OCH₂CF₃)₃ and derivaties, Sb(NR₂)₃ where R represents a generalized organic group, or the like. Sb(NMe₂)₃ is an example of a specific molecule that may be used as an antimony precursor. Deposition of an antimony coating may further include removing the precursor from the environment of the substrate, leaving antimony precursor deposited on the target surface. Deposition of an antimony coating may further include introducing one or more reagents to the target surface, which cause the antimony precursor to generate antimony. The one or more reagents may then be removed from the environment of the substrate. These operations may be repeated to generate a coating of a target thickness. The one or more reagents may include reducing reagents. The one or more reagents may include compounds such as 1,4-bis(trimethylsilyl)-2-methyl-2,5-cyclohexadiene (CHD), 1,4-bis(trimethylsilyl)-1,4-dihydropyrazine (DHP), or other reducing agents. The one or more reagents may include nitrogen-containing reagents, such as hydrazine (NH₂NH₂), hydrazine derivatives such as dimethyl hydrazines (e.g., H₂NNMe₂) and other hydrazines, ammonia, primary amines, alkyl amines, etc.

In some embodiments, a coating of bismuth may be generated on a substrate by ALD. A coating of bismuth may be generated utilizing a similar method to generating a coating of antimony. Deposition of a bismuth coating may include exposing a target to a bismuth precursor, such as bismuth chloride (BiCl₃), bismuth amino complexes such as Bi(NMe₂)₃, other bismuth halides, or other bismuth precursors. Further bismuth precursors may include BiF₃, BiBr₃, or Bib. Bismuth precursors may include triphenylbismuth. Bismuth precursors may include aryl and alkyl derivatives of BiPh₃, such as tris(4-methylphenyl)bismuthine, tris(4-fluorophenyl)bismuthine, etc. Bismuth precursors may include Bi(OCH₂CF₃)₃. Bismuth precursors may include related alkoxides of Bi(OCH₂CF₃)₃. ALD of bismuth may include use of a volatile bismuth-containing compound as a precursor. Deposition of a bismuth coating may include exposing the target and bismuth precursor to one or more co-reactants/reagents. The co-reactant may be used to convert the bismuth precursor to bismuth. The one or more reagents may include reducing reagents. The one or more reagents may include compounds such as 1,4-bis(trimethylsilyl)-2-methyl-2,5-cyclohexadiene (CHD), 1,4-bis(trimethylsilyl)-1,4-dihydropyrazine (DHP), or other reducing agents. The one or more reagents may include nitrogen-containing reagents, such as hydrazine (NH₂NH₂), hydrazine derivatives such as dimethyl hydrazines (e.g., H₂NNMe₂) and other hydrazines, ammonia, primary amines, alkyl amines, etc.

Analogous processes may be applicable for applying other elements do a surface, such as other elements of group fifteen. Analogous processes may be utilized to deposit coatings including phosphorous and/or arsenic by ALD. Chemical precursors such as phosphorous trichloride (PCl₃), phosphorous pentachloride (PCl₅), arsenic trichloride (AsCl₃), or other precursors may be utilized to perform ALD of other group 15 materials. Co-reagents, reactants, reducing agents, nitrogen-containing reagents, etc., may also be used with precursors of group fifteen materials to generate coatings.

In some embodiments, a target coating may include alloys, compounds, mixtures, multiple layers, etc. Deposition operations may include introduction of precursors of other materials to generate a target coating. In some embodiments, alternating ALD cycles may introduce precursors and co-reactants for various materials. In some embodiments, multiple ALD cycles may be performed to generate a layer of a first material, and ALD cycles may subsequently be performed to generate a layer of a second material. In some embodiments, mobilization of deposited material may be encouraged after ALD operations, e.g., by sintering. In some embodiments, a layered coating may be generated that includes bismuth, antimony, or other group fifteen elements. For example, a base coating of titanium, aluminum, or another material may be generated on a substrate. An additional layer of antimony, bismuth, other group fifteen elements, or alloys, compounds, or mixtures including group fifteen elements may be deposited by ALD on the base coating. In some embodiments, a base coating of a group 15 element may be deposited on a body, and another coating of a different composition may be deposited on top of the base coating. For example, a layer of bismuth may be deposited on a silicon substrate. A layer of titanium may be deposited on the bismuth layer. In some embodiments, a post-deposition treatment may be utilized to generate an inner layer that includes both bismuth and titanium.

In some embodiments, a coating may be deposited upon a substrate, and a second coating including bismuth, antimony, or another group fifteen element may be deposited on top of the first coating. For example, a first coating of titanium, aluminum, or antimony may be deposited on a substrate before a coating of a group 15 element. A first coating of titanium or aluminum may be deposited before a coating of antimony. A first coating of titanium, aluminum, or antimony may be deposited before a coating of bismuth. Multiple coatings of differing composition may be used to adjust properties of the substrate, to alter later deposition processes, or the like. For example, a first coating of titanium, aluminum, or antimony may promote uniformity of a second coating of bismuth. Base coating layers may be deposited by any method known in the art. In some embodiments, coating layers that do not include group 15 elements may be deposited by ALD. In some embodiments, coating layers including aluminum, titanium, and/or antimony may be deposited utilizing precursors, such as TiCl₄, AlMe₃, SbCl₃, etc.

In some aspects of the present disclosure, a method includes performing an atomic layer deposition (ALD) process to form an antimony-containing coating of a surface of a substrate. The ALD process includes providing a first reactant to the surface of the substrate. The first reactant adsorbs onto the surface to form an adsorption layer thereon. The ALD process further includes providing a second reactant to the surface of the substrate. The second reactant includes a reducing agent. The second reactant reacts with the adsorption layer to form a layer of the antimony-containing coating. The ALD process further includes repeating the providing of the first reactant and the providing of the second reactant one or more times to form the antimony-containing coating.

In some aspects of the present disclosure, a method includes performing an atomic layer deposition (ALD) process to form an bismuth-containing coating of a surface of a substrate. The ALD process includes providing a first reactant to the surface of the substrate. The first reactant adsorbs onto the surface to form an adsorption layer thereon. The ALD process further includes providing a second reactant to the surface of the substrate. The second reactant includes a reducing agent. The second reactant reacts with the adsorption layer to form a layer of the bismuth-containing coating. The ALD process further includes repeating the providing of the first reactant and the providing of the second reactant one or more times to form the bismuth-containing coating.

In some aspects of the present disclosure, a method includes performing an ALD process to form a coating containing a group fifteen element on a surface of a substrate. The ALD process includes providing a first reactant to the surface of the substrate. The first reactant comprises the group fifteen element. The first reactant adsorbs onto the surface of the substrate to form an adsorption layer thereon. The ALD process further includes providing a second reactant to the surface of the substrate. The second reactant includes a reducing agent. The second reactant reacts with the adsorption layer to form a layer of the coating containing the group fifteen element. The ALD process further includes repeating the providing of the first reactant and the providing of the second reactant one or more times to form the coating containing the group fifteen element.

In some aspects of the present disclosure, an article includes a body and a coating deposited on a surface of the body. The body comprises a first material. The coating comprises bismuth.

In some aspects of the present disclosure, an article includes a body and a coating deposited on a surface of the body. The body comprises a first material. The coating comprises a group fifteen element.

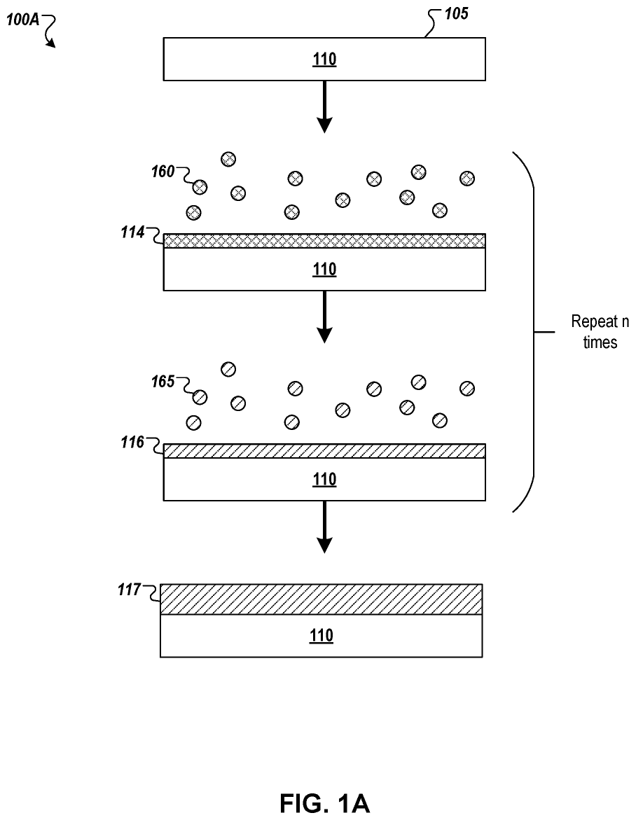

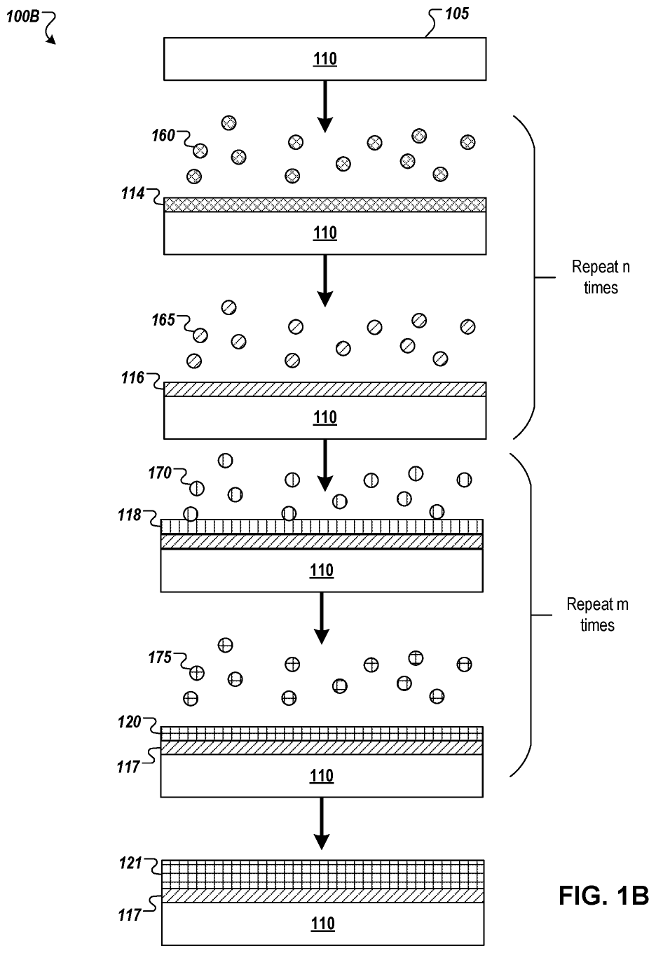

FIGS. 1A-B depict deposition processes 100A-B in accordance with an ALD technique to grow or deposit a resistant coating on a surface 105 of an article 110, according to some embodiments. Various types of ALD processes exist and the specific type utilized may be selected based on several factors such as the surface to be coated, the coating material, chemical interaction between the surface and the coating material, etc. The general principle for the various ALD processes comprises growing a thin film layer by repeatedly exposing the surface to be coated to pulses of gaseous chemical precursors that chemically react with the surface one at a time in a self-limiting manner.

FIG. 1A illustrates an article 110 having a first surface 105. Article 110 may represent various types of components, devices, substrates, etc. Article 110 may be a semiconductor device. Article 110 may be a logic device. Article 110 may be or contain an n-type semiconductor. Article 110 may include semiconductor material that primarily carries current through electrons, rather than electron holes. Article 110 may be constructed from a metal (such as aluminum, titanium, cobalt, copper, ruthenium, tungsten, platinum or stainless steel), a polymer, silicon, a ceramic material, or any other suitable material. Article 110 may be a semiconductor device that is to be used for an application for which standard contact materials (such as TiSi₂) are not ideal. Article 110 may be a semiconductor device that would benefit from contact materials that have a work function value within a target range.

For ALD, either adsorption of a precursor onto a surface or a reaction of a reactant with the adsorbed precursor may be referred to as a “half-reaction.” During a first half reaction, a precursor is provided to a volume proximate to surface 105 of article 110 for a period of time sufficient to allow the precursor to fully adsorb onto the surface. The adsorption is self-limiting as the precursor will adsorb onto a finite number of available sites on the surface, forming a uniform continuous adsorption layer on the surface. Any sites that have already adsorbed with a precursor will become unavailable for further adsorption with the same precursor unless and/or until the adsorbed sites are subjected to a treatment that will form new available sites on the uniform continuous coating. Exemplary treatments may be plasma treatment, treatment by exposing the uniform continuous adsorption layer to radicals, or introduction of a different precursor able to react with the most recent uniform continuous layer adsorbed to the surface.

In some embodiments, two or more precursors are injected together and adsorbed onto the surface of an article. The excess precursors are pumped out until a reactant (e.g., an oxygen-containing reactant) is injected to react with the adsorbates to form a solid single phase or multi-phase layer (e.g., of YAG, of alumina, etc.). This fresh layer is ready to adsorb the precursors in the next cycle.

Article 110 may be introduced to a first precursor 160 for a first duration until surface 105 of article 110 is fully adsorbed with the first precursor 160 to form an adsorption layer 114. Subsequently, article 110 may be introduced to a first reactant 165 to react with the adsorption layer 114 to grow a solid layer 116 (e.g., so that the layer 116 is fully grown or deposited, where the terms grown and deposited may be used interchangeably herein). The first precursor 160 may be a precursor for a group 15 element. The first precursor 160 may be a precursor for a group 15 metal, non-metal, or metalloid. The first precursor 160 may be a bismuth precursor. The first precursor 160 may be an antimony precursor. The first precursor 160 may be a phosphorus or arsenic precursor.

Bismuth precursors may include BiCl₃. Bismuth precursors may include bismuth amido complexes, Bi(NR₂)₃, where R represents a generic group. Common examples may include Bi(NMe₂)₃, Bi(NEt₂)₃, Bi(NMeEt)₃, Bi(N(SiMe₃)₂)₃, Bi(NMe(SiMe₃))₃, and other bismuth amido complexes. Bismuth precursors may include other volatile bismuth-containing materials. Antimony precursors may include SbCl₃. Antimony precursors may include antimony halides. Antimony precursors may include compounds of the form SbX₃, where X represents a halide. Antimony precursors may include SbF₃, SbBr₃, SbI₃, etc. Antimony precursors may include mixed halides, e.g., SbCl₂F. Antimony precursors may include triphenylantimony. Antimony precursors may include triphenylantimony derivaties. Antimony precursors may include Sb(OCH₂CF₃)₃ and related alkoxides, Sb(NR₂)₃ where R represents a generic group, or other volatile Sb precursors. Phosphorus precursors may include phosphorus trichloride PCl₃ or other phosphorus precursors. Arsenic precursors may include arsenic trichloride AsCl₃ or other arsenic precursors.

The first precursor 160 and first reactant 165 (which may also be referred to as a precursor, co-reactant, reagent, etc.) may be used to form a coating on surface 105. Accordingly, ALD may be used to form layer 116. Layer 116 may be a layer consisting substantially of a group 15 element. Layer 116 may be a layer of bismuth. Layer 116 may be a layer of antimony. Layer 116 may be a layer of phosphorus or arsenic. Layer 116 may be a mono-layer of group 15 atoms. Layer 116 may be one layer of a multi-layer coating.

To generate a coating (or a coating layer) of a group 15 element, article 110 may be introduced to first precursor 160. First precursor 160 may include a compound or complex that includes one or more atoms of the target group 15 element. Article 110 may be exposed to first precursor 160 for a first duration until all reactive sites on surface 105 of article 110 are consumed. Article 110 may be exposed to first precursor 160 for a first duration until a target portion of reactive sites on surface 105 are consumed. Remaining first precursor 160 may be removed. Remaining first precursor 160 may be removed by evacuating a volume adjacent to surface 105. Remaining first precursor 160 may be removed by flushing volume adjacent to surface 105 with a gas. A flushing gas may be an inert gas, such as a noble gas, nitrogen, or the like.

First reactant 165 may be injected into the volume proximate to surface 105 to start the second half-cycle of the ALD deposition process. First reactant 165 may be a material that interacts with layer 114 to convert layer 114 to a target material. First reactant 165 may convert a precursor material to a target material. First reactant 165 may convert a precursor containing a group 15 element into a coating layer of the group 15 element. The first reactant 165 may be a reducing agent. First reactant 165 may reduce a group 15 precursor to generate a coating of the group 15 material. First reactant 165 may be a reducing agent such as 1,4-bis(trimethylsilyl)-2-methyl-2,5-cyclohexadiene (CHD), 1,4-bis(trimethylsilyl)-1,4-dihydropyrazine (DHP), or other reducing agents. First reactant 165 may be a nitrogen-containing reactant. Nitrogen-containing reactants may include NH₃, alkyl amines such as tert-BuNH₂, hydrazine (N₂H₄) and alkyl substituted hydrazines, etc. Alkyl substituted hydrazines may include tert-butylhydrazine, symmetric and unsymmetrical dimethylhydrazine, etc. Without being bound by theory, it is believed that some nitrogen-containing co-reactants may form an unstable bond between a nitrogen atom and a group 15 atom. The unstable bond decays, leaving a layer composed primarily of the group 15 material. First reactant 165 may be allowed to interact with layer 114 for a duration sufficient to allow all the precursor of layer 114 to be converted to a target material of layer 116. First reactant 165 may be allowed to interact with layer 114 for a duration sufficient to allow a target portion of precursor of layer 114 to be converted to the target material of layer 116. Remaining first reactant 165 may be removed. Remaining first reactant 165 may be evacuated, flushed, replaced, or the like, similar to excess first precursor 160 previously. Bismuth deposition may be performed with substrate temperature between 70° C. and 225° C. Bismuth deposition may be performed with substrate temperatures between 125° C. and 175° C. Antimony deposition may be performed with substrate temperature between 75° C. and 150° C.

ALD operations may be performed at a controlled temperature. ALD operations may be performed while maintaining a controlled temperature of article 110. ALD operations may be performed while maintaining a substrate temperature of about 175° C., about 150° C., about 125° C., about 100° C., about 75° C., about 70° C., or the like.

Layer 116 may be uniform, continuous and conformal. Layer 116 may be porosity free (e.g., have a porosity of zero) or have an approximately zero porosity in embodiments (e.g., a porosity of 0% to 0.01%). Layer 116 may have a thickness of less than one atomic layer to a few atoms in some embodiments after a single ALD deposition cycle. Some precursor molecules are large. After reacting with reactant 165, large organic ligands may be gone, leaving much smaller metal atoms. One full ALD cycle (e.g., that includes introduction of precursors 160 followed by introduction of reactants 165) may result in less than a single atomic layer.

Multiple full ALD deposition cycles may be implemented to deposit a thicker layer 117 (up to >100 nm thickness), with each full cycle (e.g., including introducing precursor 160, flushing, introducing reactant 165, and again flushing) adding to the thickness by an additional fraction of an atom to a few atoms. As shown, up to n full cycles may be performed to grow layer 117, where n is an integer value greater than 1. In some embodiments, layer 117 may have a thickness of about 1 nm to about 5 μm. In some embodiments, layer 117 may have a thickness of about 1 nm to 500 nm. In some embodiments, layer 117 may have a thickness of about 10 nm to 100 nm. In some embodiments, layer 117 may have a thickness of about 20 nm, about 40 nm, or about 80 nm. In some embodiments, layer 117 may have a thickness of about 100 nm to about 1 μm. In some embodiments, layer 117 may have a thickness of about 200 nm to about 800 nm. In some embodiments, layer 117 may have a thickness of about 300 nm to about 600 nm. In some embodiments, layer 117 may have a thickness of about 400 nm to about 500 nm, or any permutation, combination, or included ranges of the above thicknesses.

Layer 117 deposited on article 110 may composed substantially of antimony or bismuth. Layer 117 deposited on article 110 may be composed substantially of phosphorus or arsenic. Layer 117 deposited on article 110 may be composed of a mixture of group 15 element. Layer 117 may be composed of a mixture of group 15 elements and other elements. Layer 117 may include group 15 oxides.

Surface 105 of article 110 may be of many types of material. Surface 105 may be a semiconductor material. Surface 105 may be a metallic material. Surface 105 may be of silicon. Surface 105 may be of silicon dioxide (SiO₂). Surface 105 may be of hydride-terminated silicon, e.g., silicon treated by submersion in HF. Surface 105 may be of silicon that has been exposed to a hydride source. Surface 105 may be of cobalt, copper, ruthenium, tungsten, platinum, titanium, etc. Surface 105 may be of a ceramic material.

Surface 105 may be of titanium nitride. Surface 105 may be characterized by a Miller index associated with the orientation of surface 105 compared to a crystal structure arrangement of article 110. Deposition may be performed on a silicon substrate with a Miller index of (111), (110), (100), etc. Deposition of layer 117 may be preferentially performed on a particular plane (as described by a Miller index). For example, bismuth deposition may more easily coat silicon (111) substrates than other surface orientations.

Layer 117 may provide target properties to article 110. Layer 117 may adjust properties of article 110. Layer 117 may be composed of a material that, for example, exhibits a favorable work function, favorable electric properties, favorable optical or mechanical properties, or the like. Layer 117 may act as a contact for a semiconductor device. Layer 117 may improve operation of article 110. Layer 117 may reduce a threshold voltage of a semiconductor logic device. Layer 117 may reduce energy used to operate article 110.

Layer 417 may be substantially composed of a group 15 element. Layer 417 may have a purity of 80% or higher. Layer 417 may have a purity of 85% or higher. Layer 417 may have a purity of 90% or higher. Layer 417 may have a purity of 95% or higher.

FIG. 1B describes a deposition process 100B that includes deposition layer 117 as described with reference to FIG. 1A. Deposition process 100B of FIG. 1B further includes deposition of an additional layer 121 to form a multi-layer coating. Accordingly, after layer 117 is complete, article 110 may be introduced to an additional one or more precursors 170 for a second duration until layer 117 is fully adsorbed with the one or more additional precursors 170 to form an adsorption layer 118. Subsequently, article 110 may be introduced to a reactant 175 to react with adsorption layer 118 to grow a solid layer 120, also referred to as a second layer 120. Second layer 120 may, similar to the layer depicted in FIG. 1A, be deposited multiple times (e.g., m depositions), to generate a second layer 121 of a target thickness. Different ratios of thicknesses between layer 117 and layer 121 may generate different properties, e.g., corrosion resistance, heat resistance, mechanical strength, differences in resistance to damage due to thermal expansion, electric conductivity, etc.

In some embodiments, layer 116 may improve deposition of further material. Layer 116 may be of a material that promotes nucleation, promotes deposition and/or adhesions, and/or enables deposition of a continuous film on top of layer 116. For example, target layer 121 may be of a group 15 element. Layer 116 may be of a material that improves properties of target layer 121, such as an intermediate layer that bonds well to both article 110 and layer 121. Layer 116 may be of a material to promote development of a bismuth and/or antimony film above layer 116. Layer 116 may be of titanium, aluminum, or antimony. Layer 116 may be formed by any thin layer deposition technique known. Layer 116 may be deposited by ALD. Layer 116 may be deposited utilizing a deposition precursor, such as TiCl₄, AlMe₃, SbCl₃, etc. Layer 116 may be a seed layer to assist in developing layer 121.

In some embodiments, a group 15 element may be deposited beneath a layer of a second material, e.g., layer 116 may be of a group 15 element. Layer 121 may be of a different material, deposited on top of the group 15 element. For example, a contact for a semiconductor device may include a lower layer of or including a group 15 element and an upper layer of another material. A layer of titanium may be deposited above a layer of a group 15 element. A layer of titanium may be deposited above a layer of bismuth or antimony.

In some embodiments, deposited layers may be treated, annealed, sintered, or otherwise allowed to interact. Material from one layer may infiltrate, intersperse with, or otherwise interact with material from another layer. An intermediate layer including material from two adjacent layers may be generated. Composition of one or more layers may be altered. For example, layer 116 may be of a group 15 element and layer 121 may be of titanium. After further treatment, article 110 may have a layer including both a group 15 element and titanium, and an upper layer including titanium. Article 110 may have a layer thereon of a group 15 element, a further layer including the group 15 element and titanium, and a further layer of titanium.

In some embodiments, other sequences of depositions may be performed, for example to generate a coating of an alloy, compound, complex, or the like. Precursor 160 may include precursors for more than one material. Layer 116 may include multiple materials. For example, precursor 160 may include bismuth precursor and another metal precursor, and layer 116 may be composed of an alloy of bismuth and the other metal. In some embodiments, precursor 160 and precursor 170 may each be deposited in multiple alternating layers. A layer of a first material associated with precursor 160 may be deposited, followed by a layer of a second material associated with precursor 170.

Further layers of the first and second material may continue to be deposited. Later treatment may allow materials from the deposited layers to interact. Any operations associated with FIGS. 1A-B may be extended to facilitate incorporation of additional materials, such as a third coating layer. Operations associated with FIGS. 1A-B may be extended to facilitate incorporation of additional materials into a coating layer including multiple materials.

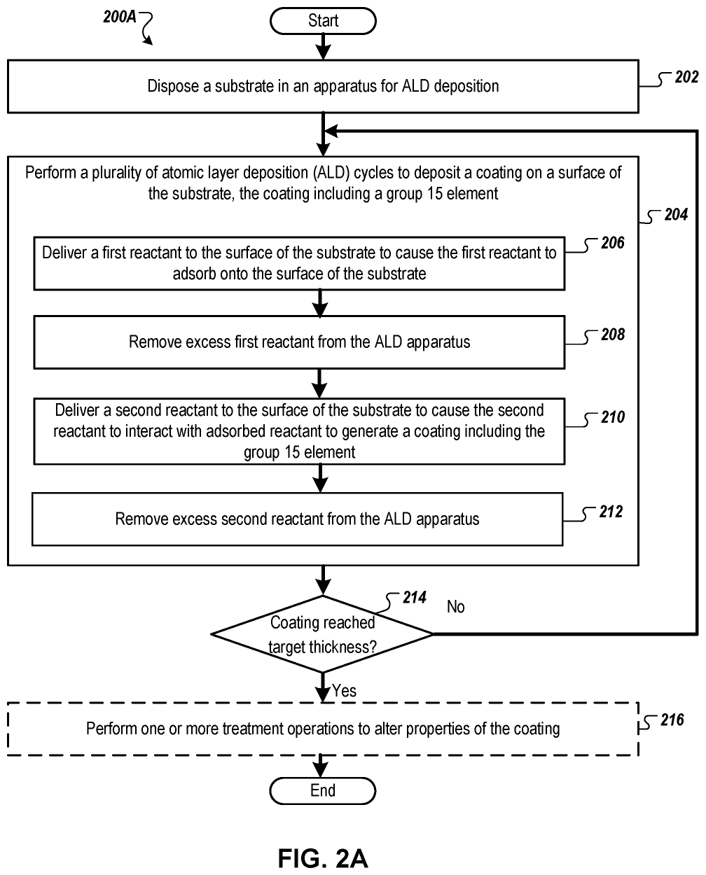

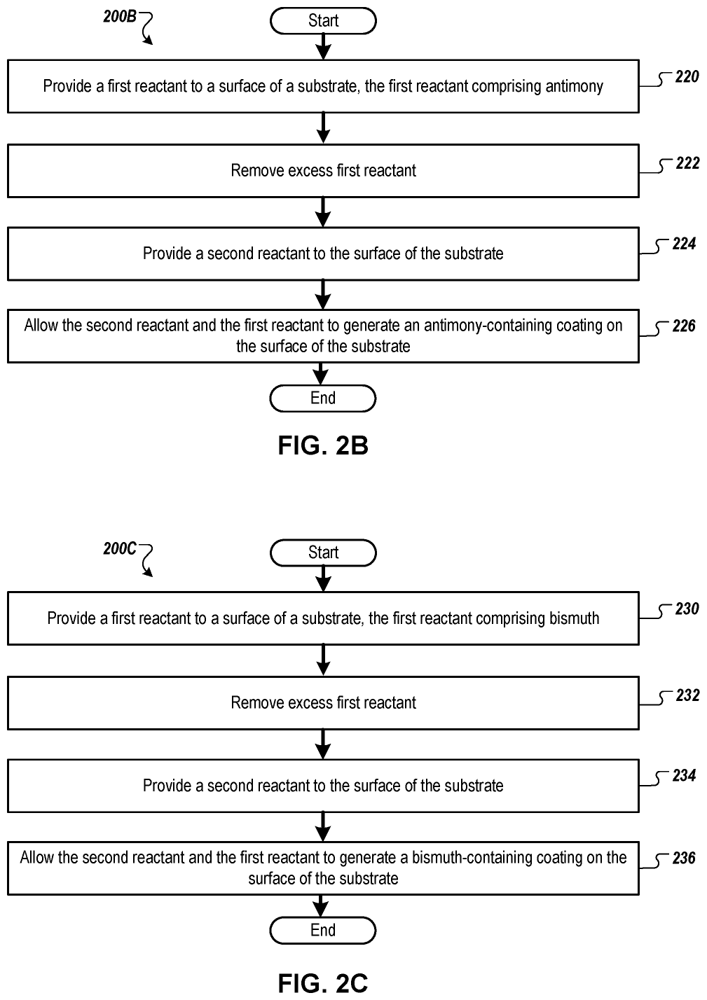

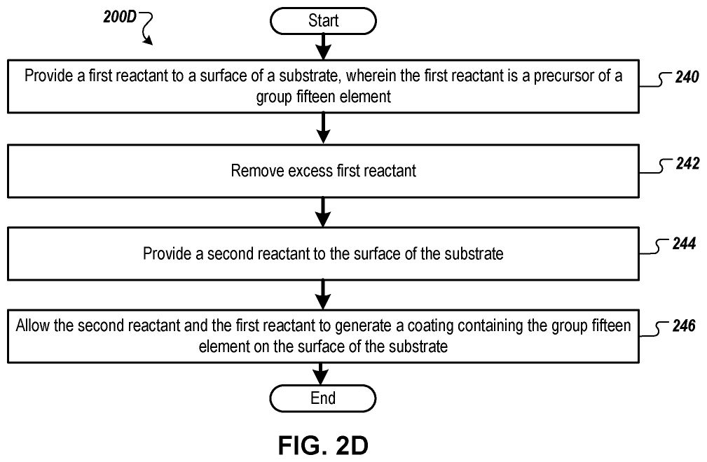

FIG. 2A is a flow diagram of a method 200A for depositing a coating including a group 15 element on a substrate, according to some embodiments. At block 202, the substrate is disposed in an ALD deposition apparatus. ALD may be performed in a chamber that seals an interior volume from the environment. The substrate may be placed in the interior volume. The ALD chamber may include fixtures for supplying and evacuating various gases. The ALD apparatus may include a vacuum chamber. The ALD apparatus may include various forms of temperature control, such as heaters, heat exchangers, cooling lines, etc. The ALD apparatus may include means for maintaining a target substrate temperature. The ALD apparatus may include means for maintaining a target temperature of gas input to the apparatus, which may be different than the target temperature of the substrate. The ALD apparatus may include any tubing, lines, valves, gauges, pumps, nozzles, or the like, to enable operation of the ALD apparatus.

In some embodiments, some processing of the substrate may be performed before it is disposed within the ALD apparatus. A coating may be applied previous to the ALD coating including the group 15 element. Surface preparations for deposition such as etching or masking may be performed. A hydride source may be introduced to silicon to generate a Si—H terminated substrate surface.

At block 204, a plurality of atomic layer deposition cycles are performed. The ALD cycles deposit a coating on a surface of the substrate. The ALD cycles deposit a coating including a group 15 element on the surface of the substrate. The ALD cycles may deposit a coating including antimony. The ALD cycles may deposit a coating consisting essentially of antimony. The ALD cycles may deposit a coating including bismuth. The ALD cycles may deposit a coating consisting essentially of bismuth. The ALD cycles may deposit a coating including or consisting essentially of phosphorus or arsenic. ALD deposition of a coating may be separated into sub-operations, described in blocks 206-212.

At block 206, a first reactant is delivered to the surface of the substrate. The first reactant is adsorbed onto the surface of the substrate. In some embodiments, the first reactant may form the adsorbed material. For example, interaction with the surface may facilitate adsorption of a material different from the delivered first reactant, e.g., by surface-catalyzed bond rearrangement. The first reactant may be or include a precursor for a target coating material. The first reactant may include a precursor for a group 15 element. The first reactant may include a precursor for a bismuth coating. The first reactant may include a precursor for an antimony coating. The first reactant may include a precursor for a phosphorus or arsenic coating. The first reactant may include SbCl₃, SbX₃ where X represents one or more halides, Sb(OCH₂CF₃)₃ or related alkoxides, Sb(NR₂)₃, BiCl₃, BiX₃, Bi(NR₂)₃, AsCl₃, or PCl₃, where R represents a generic group.

At block 208, excess first reactant is removed from the ALD apparatus. The excess first reactant may be removed via evacuating a chamber of the ALD apparatus that contains the substrate. The excess first reactant may be removed via flushing a chamber of the ALD apparatus containing the substrate with a gas. The ALD apparatus may be flushed with a non-reactive gas. The ALD apparatus may be flushed with a noble gas, nitrogen, or another gas to remove excess first reactant.

At block 210, a second reactant is delivered to the surface of the substrate. The second reactant interacts with material adsorbed onto the surface of the substrate. The second reactant may interact with the first reactant adsorbed to the surface of the substrate. The second reactant may react with the adsorption layer on the surface of the substrate. The second reactant may interact with the first reactant to generate a target coating material. The second reactant may interact with the first reactant to generate a coating including a group 15 element. The second reactant may be a reducing agent. The second reactant may be DHP. The second reactant may be CHD. The second reactant may be or include a nitrogen source. The second reactant may be N₂H₄. The second reactant may be H₂NNMe₂. The second reactant may be NH₃. The second reactant may be an alkyl amine. The second reactant may be tert-BuNH₂. The second reactant may be hydrazine. The second reactant may be a substituted hydrazine derivative (R₂NNR₂). The second reactant may be a substituted hydrazine such as tert-BuHNNH₂, MeHNNHMe, H₂NNMe₂, etc. Without being bound by theory, it is believed that nitrogen-containing second reactants may form an unstable nitrogen bond with a group 15 element. The nitrogen bond may decay spontaneously, leaving a coating of the group 15 element.

At block 212, excess second reactant is removed from the ALD apparatus. Operations of block 212 may share one or more features with operations of block 208.

At block 214, a determination is made regarding whether the coating deposited in the ALD process of block 204 has reached a target thickness. Thickness determination may be made in response to measuring a thickness of a coating, tracking how many cycles of block 204 have been performed, etc. If a target thickness has not been reached, operations of block 204 may be repeated. The operations of block 204 may be referred to as an ALD cycle. In some embodiments, a target coating thickness may be between 1 nm and 5 μm. In some embodiments, many ALD cycles may be performed to achieve a coating with the target thickness, e.g., many thousands of ALD cycles. Performance of a large number of ALD cycles may be costly in terms of time spent, energy expended (e.g., energy to maintain ALD deposition temperatures), material expended, etc. Diffusion of ALD gases into complex internal geometries, e.g., internal channels in a component of a gas delivery system, may be very time consuming. Utilizing a pumping system to selectively drive flow of ALD gases in regions where a coating is to be deposited may alleviate long deposition times by providing ALD gases directly to surfaces to be coated, and directly evacuating volumes proximate to those surfaces. If a target thickness has been reached, flow continues to block 216.

At block 216, one or more treatment operations are optionally performed. Treatment operations may alter properties of the coating deposited on the surface of the substrate. In some embodiments, post-treatment operations may include depositing further material on the surface of the substrate. In some embodiments, post-treatment operations may include depositing a further layer of a different material on top of a layer including the group 15 element. Post-treatment may include operations to alter composition of one or more layers on the surface of the substrate. Post-treatment may enable migration of atoms between layers. Post-treatment may generate an alloy, compound, or complex material from compounds of multiple deposited layers.

FIG. 2B is a flow diagram for a method 200B for generating an antimony-containing coating on a substrate, according to some embodiments. At block 220, a first reactant is provided to a surface of a substrate. The first reactant includes antimony. The first reactant may be an antimony precursor. The first reactant may be a volatile compound that includes antimony. The first reactant may be SbCl₃, Sb(OCH₂CF₃)₃, or Sb(NR₂)₃. The first reactant may be an antimony halide.

At block 222, excess first reactant is removed. Excess first reactant may be removed via pumping, flushing, or other methods known in the art.

At block 224, a second reactant is provided to the surface of the substrate. The second reactant interacts with the first reactant. The second reactant may be a reducing agent. The second reactant may be a nitrogen source.

At block 226, The second reactant and the first reactant are allowed to interact. The second reactant and the first reactant interact to generate an antimony-containing coating. The coating may be primarily composed of antimony. The coating may include antimony and other materials. Operations of method 200B may be repeated to generate a coating of a target thickness.

FIG. 2C is a flow diagram of a method 200C for generating a bismuth-containing coating on a substrate, according to some embodiments. Operations of method 200C may be similar to operations of method 200B of FIG. 2B. At block 230, a first reactant is provided to a surface of a substrate. The first reactant includes bismuth. The first reactant may be BiCl₃, another bismuth halide, a bismuth amido complex, Bi(NR₂)₃, or other volatile bismuth-containing compound. At block 232, excess first reactant is removed. At block 234, a second reactant is provided to the surface of the substrate. The second reactant may be a reducing agent. The second reactant may be a nitrogen source. At block 236, the second reactant and the first reactant are allowed to interact. The reactants interact to generate a bismuth-containing coating on the surface of the substrate. The coating may substantially consist of bismuth.

FIG. 2D is a flow diagram of a method 200D for generating a coating including a group 15 element, according to some embodiments. At block 240, a first reactant is provided to a surface of a substrate. The first reactant is a precursor of a group 15 element. The group 15 element may be antimony, bismuth, phosphorus, or arsenic. The first reactant may be a volatile compound including the target group 15 element. The first reactant may be a chloride of the group 15 element.

At block 242, excess first reactant is removed from a region proximate to the surface of the substrate. At block 244, a second reactant is provided to the surface of the substrate. The second reactant may be a reducing agent. The second reactant may be a nitrogen source. At block 246, the second reactant ad the first reactant are allowed to interact. The reactants generate a coating on the surface of the substrate. The reactants generate a coating containing the group 15 element.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

1. A method, comprising:
performing an atomic layer deposition (ALD) process to form an antimony-containing coating on a surface of a substrate, the ALD process comprising:
providing a first reactant to the surface of the substrate, the first reactant comprising antimony, wherein the first reactant adsorbs onto the surface of the substrate to form an adsorption layer thereon;
providing a second reactant to the surface of the substrate, wherein the second reactant comprises a reducing agent, and wherein the second reactant reacts with the adsorption layer to form a layer of the antimony-containing coating; and
repeating the providing of the first reactant and the providing of the second reactant one or more times to form the antimony-containing coating.

2. The method of claim 1, wherein the first reactant is chosen from a group consisting of:
SbCl₃;
SbF₃;
SbBr₃;
SbI₃;
Sb(OCH₂CF₃)₃;
Sb(NR₂)₃, wherein R represents a generic group; and
combinations thereof.

3. The method of claim 1, wherein the second reactant is chosen from a group consisting of:
DHP;
CHD;
hydrazine;
R₂NNR₂, wherein R represents a generic group;
ammonia;
primary amines;
alkyl amines; and
combinations thereof.

4. The method of claim 1, wherein the substrate comprises a semiconductor device.

5. The method of claim 4, further comprising pretreating the surface of the substrate by introduction of a hydride source to generate a hydride-terminated surface.

6. The method of claim 4, wherein the substrate comprises a Si(111) substrate.

7. The method of claim 1, further comprising:
pretreating the surface of the substrate by depositing a second coating material on the surface prior to providing the first reactant to the surface.

8. The method of claim 7, wherein the second coating material comprises titanium or aluminum.

9. A method, comprising:
performing an atomic layer deposition (ALD) process to form a bismuth-containing coating on a surface of a substrate, the ALD process comprising:
providing a first reactant to the surface of the substrate, the first reactant comprising bismuth, wherein the first reactant adsorbs onto the surface of the substrate to form an adsorption layer thereon;
providing a second reactant to the surface of the substrate, wherein the second reactant comprises a reducing agent, and wherein the second reactant reacts with the adsorption layer to form a layer of the bismuth-containing coating; and
repeating the providing of the first reactant and the providing of the second reactant one or more times to form the bismuth-containing coating.

10. The method of claim 9, wherein the first reactant is chosen from a group consisting of:
bismuth amido complexes;
BiCl₃;
BiF₃;
BiBr₃;
BiI₃;
BiPh₃;
Bi(OCH₂CF₃)₃; and
combinations thereof.

11. The method of claim 9, wherein the second reactant is chosen from a group consisting of:
DHP;
CHD;
hydrazine;
R₂NNR₂, wherein R represents a generic group;
ammonia;
primary amines;
other alkyl amines; and
combinations thereof.

12. The method of claim 9, further comprising:
pretreating the surface of the substrate by depositing a second coating material on the surface prior to providing the first reactant to the surface.

13. The method of claim 12, wherein the second coating material comprises titanium, antimony, or aluminum.

14. A method, comprising:
performing an atomic layer deposition (ALD) process to form a coating containing a group fifteen element on a surface of a substrate, the ALD process comprising:
providing a first reactant to the surface of the substrate, the first reactant comprising the group fifteen element, wherein the first reactant adsorbs onto the surface of the substrate to form an adsorption layer thereon;
providing a second reactant to the surface of the substrate, wherein the second reactant comprises a reducing agent, and wherein the second reactant reacts with the adsorption layer to form a layer of the coating containing the group fifteen element; and
repeating the providing of the first reactant and the providing of the second reactant one or more times to form the coating containing the group fifteen element.

15. The method of claim 14, wherein the first reactant is a chloride of the group fifteen element.

16. The method of claim 14, further comprising:
providing a third reactant to the surface of the substrate, wherein the third reactant comprises a second material, wherein the second material is different than the group fifteen element;
providing a fourth reactant to the surface of the substrate, wherein the fourth reactant reacts with the third reactant to form a layer of the second material; and
repeating the providing of the third reactant and the providing of the fourth reactant one or more times to form a coating of the second material.

17. The method of claim 14, further comprising:
generating a second coating of a second material on the first coating, wherein the second material is different than the group fifteen element; and
treating the substrate to generate an intermediate coating layer, the intermediate coating layer including the group fifteen element and the second material.

18. The method of claim 14, further comprising treating the substrate with the coating on the surface to generate an intermediate layer between the coating and the substrate.

19-31. (canceled)
